(19) United States
(12) Patent Application Publication
(10) Pub. No.: US 2004/0140115 A1
(43) Pub. Date: Jul. 22, 2004

(54) Contacting component

(76) Inventors: Georg Fischer, Reifenthal (DE); Harald Holzer, Kammern (AT); Andreas Rekofsky, Mintraching (DE); Karl Smirra, Wasserburg (DE)

Correspondence Address: BAKER BOTTS L.L.P., PATENT DEPARTMENT, 98 SAN JACINTO BLVD., SUITE 1500, AUSTIN, TX, 78701-4039, US

(21) Appl. No.: 10/735,159

(22) Filed: Dec. 12, 2003

(30) Foreign Application Priority Data
Dec. 20, 2002 (DE) DE10260241.7

(51) Int. Cl. H05K 5/06

(52) U.S. Cl. 174/52.2

(57) ABSTRACT

A contacting component for manufacturing an electrically conductive connection includes a conductor device (2) onto which at least one first plastic component (3) and separately a second plastic component (4, 5, 6) are molded in which case the conductor device (2) can be bent in such a way that the first plastic component (3) can engage in the second plastic component (4, 5, 6) to provide an integral contacting component.

### PRIORITY

This application claims foreign priority of the German application DE 10260241.7 filed on Dec. 20, 2002.

### TECHNICAL FIELD OF THE INVENTION

This invention relates to a contacting component for providing an electrically conductive connection between an electronic or control/regulation device and an actuator, in particular, a valve for the hydraulic control in a transmission as well as a method for manufacturing a contacting component.

### BACKGROUND OF THE INVENTION

Valves for the hydraulic control of transmissions, especially automatic transmissions, are actuated, for example, by means of magnets or by means of piezoelements to control a fluid flow. This involves resolving the problem of making contact between the valve and, for example, a control/regulation device. Furthermore, a certain degree of tolerance compensation between the valve and the contacting component connected to it must be possible. Therefore, contact was previously made with the valves by means of flexible printed circuit boards (flexible foils) so that a sufficient tolerance compensation is also possible. However, these types of flexible printed circuit boards are very costly to manufacture and moreover extremely expensive.

A contacting component for manufacturing an electrically conductive connection is known from publication U.S. Pat. No. 5,619,012 A, in which two separate plastic components are molded onto one conductor device that fit closely together after the conductor device has been bent into its final position.

### SUMMARY OF THE INVENTION

Therefore, the object of this invention is to provide a contacting component for manufacturing an electrically conductive connection that allows safe contacting and a sufficient tolerance compensation and must therefore be embodied particularly simply and manufactured cost-effectively. It is also the object of this invention to provide a method for manufacturing a finished contacting component.

The object of the invention can be achieved by a contacting component for manufacturing an electrical connection, in particular, between a control/regulation device and an actuator comprising a conductor device onto which at least one first plastic component and, separately from it, a second plastic component are molded in which case the conductor device can be bent in such a way that the first plastic component can engage in the second plastic component to provide an integral contacting component.

The first plastic component and/or the second plastic component may have a bending collar around which the conductor device can be bent. The first plastic component can engage in the second plastic component by means of a snap-in locking device. The first plastic component in the engaged state may have an angle of approximately 90° to the second plastic component.

The object can also be achieved by a method for manufacturing a contacting component that provides an electrically conductive connection, in particular, between an electronic or control/regulation device and an actuator including the following steps:

Providing a conductor device,

Molding a first plastic component and a second plastic component onto the conductor device wherein the second plastic component is arranged separately from the first plastic component, and

Bending the conductor device in such a way that the first plastic component engages in the second plastic component to obtain an integral contacting component.

At least one of the plastic components may have a bending collar around which the conductor device can be bent. The plastic components can be molded simultaneously onto the conductor device. The first plastic component can be connected to the second plastic component by means of a releasable snap-in locking device. The conductor device can be removed from a flat blank in such a way that individual track conductors are interconnected via connecting bars and the connecting bars are removed after molding the plastic components. The conductor device may include several separate track conductors which are kept in predetermined positions by means of a holding device and the plastic components are then molded onto the track conductors held in this position and the holding device is removed after the molding process has ended.

The contacting component according to the invention for manufacturing an electrically conductive connection, in particular, between a control/regulation device and an actuator such as, for example, a valve for the hydraulic control in a transmission, includes a conductor device onto which a first plastic component and a second plastic component are molded. Therefore, the conductor device is embodied in such a way as to be flexible so that when bending the conductor device, the first plastic component can be engaged in the second plastic component to provide an integral contacting component. By means of the contacting component according to the invention it is therefore possible to abandon the extremely expensive flexible foils used thus far in the prior art. Therefore, the conductor device provides the contacting function according to the invention and the tolerance compensation function is resolved on the basis that at least two separate plastic components are molded onto the conductor device. As a result, the two plastic components are interconnected via a conductor device. By bending and mutual engagement of at least the two plastic components, the conductor device takes over a required tolerance compensation, if required. In this case, the conductor device can for example be a simple, wire-shaped metallic conductor.

Particularly favorably, the first and/or the second plastic component feature a bending collar around which the conductor device can be bent. As a result, additional tools or auxiliary means when engaging the two plastic components can be dispensed with. The conductor device is then bent automatically when assembling the contacting component. In addition, the bending process can then be automated cost-effectively.

Advantageously, a snap-in locking device interconnects the two plastic components. Therefore, freedom of movement to compensate for tolerances of the conductor device can be ensured in a particularly simple way. In addition, the snap-in locking devices can also immediately be molded integrally with the plastic components so that they are formed in one piece with the plastic components.

The contacting component is embodied particularly favorably in such a way that the first plastic component in the end state, i.e. in the engaged state is arranged at an angle of approximately 90° to the second plastic component. In that way, the conductor device can consist of several, in essence, plane wire or striped printed circuit boards arranged parallel to one another in which case the plastic components are molded onto the printed circuit boards.

The method according to the invention for manufacturing a contacting component includes the steps of providing the conductor device, molding a first and second plastic component onto the conductor device in such a way that the first and second plastic components are arranged separately from one another on the conductor device and the bending over of the semi-finished product formed in this way that the first plastic component engages in the second plastic component.

The two plastic components are molded particularly favorably simultaneously onto the conductor device. Favored further is the fact that integral snap-in locking elements are also molded onto the plastic components to allow an interlocking of the two plastic components after bending over.

The conductor device is preferably a lattice element that is removed from a flat blank, e.g. by means of punching or laser separation in such a way that individual track conductors are interconnected at one end via connecting bars and the connecting bars are removed after molding the plastic components to prevent a short-circuit during operation. Therefore, the connecting bars can be removed before or after bending the semi-finished product.

According to a preferred development of the method according to the invention, the conductor device includes several separate track conductors which, in particular, are kept parallel to one another in predetermined positions by means of a holding device. The two plastic components are then molded onto the track conductors held in this way and after the molding process has ended and the plastic components have hardened, the holding device is removed so that the semifinished product is kept that is finally assembled by bending over the conductor and engaging the two plastic components in the contacting component.

The contacting component according to the invention can, in particular, be used in transmissions for motor vehicles to provide a robust and non-sensitive connection as regards the hydraulic oil.

### BRIEF DESCRIPTION OF THE DRAWINGS

The invention is described below on the basis of a preferred embodiment together with the accompanying drawings. They are as follows:

FIG. 1 a schematic, perspective view of a contacting component according to an embodiment of the invention in an intermediate state (semi-finished product),

FIG. 2 a schematic sectional view of the contacting component of FIG. 1,

FIG. 3 a schematic, perspective view of the contacting component in the final assembled state, and

FIG. 4 a schematic sectional view of the end state of the contacting component shown in FIG. 3.

### DETAILED DESCRIPTION OF THE PREFERRED EMBODIMENTS

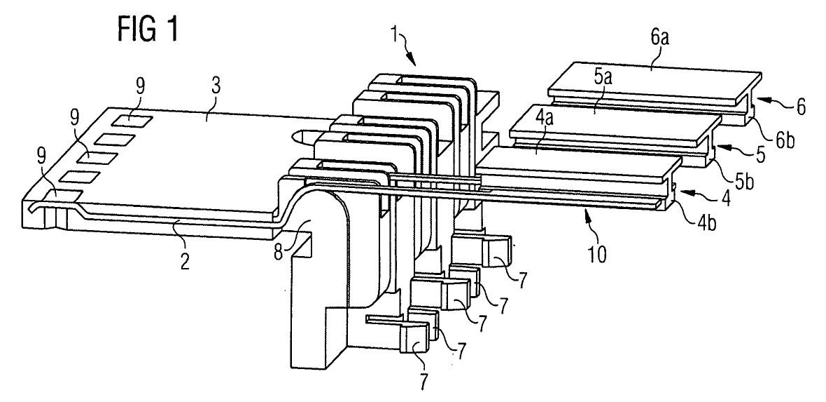

An embodiment of this invention is described below with reference to FIGS. 1 to 4.

As can, in particular, be seen in FIG. 1 according to the invention, the contacting component 1 includes a conductor device 2 that consists of many parallel track conductors. Therefore, the individual track conductors are not electrically interconnected and, in essence, have a striped design. On the track conductors, a base component 3 of plastic is molded onto one end thereof, on the one hand, and onto the other end of the track conductors, valve plugs 4, 5, 6 are molded on via which contact is made with the valves (actuators) that are not shown. Therefore, the valve plugs 4, 5, 6 are embodied in such a way that they have a plate-shaped area 4a, 5a, 6a on one side and a T carrier-shaped area 4b, 5b, 6b on the other side on which the track conductors are arranged.

Therefore, the individual track conductors of the conductor device 2 have a first contact area 9 in each case on the base component 3 and a second contact area 10 on the valve plugs 4, 5, 6. The conductor device 2 is preferably manufactured for the application shown with valve contact areas 10 for three valves in such a way that, in essence, from a flat rectangular blank of metallic material, the individual track conductors are punched out in one step and, if required, have already been bent partially. The base area 3 or the relevant valve plugs 4, 5, 6 are then molded onto the ends of the individual track conductors by means of plastic molding so that a semi-finished product as shown in FIG. 1 is obtained.

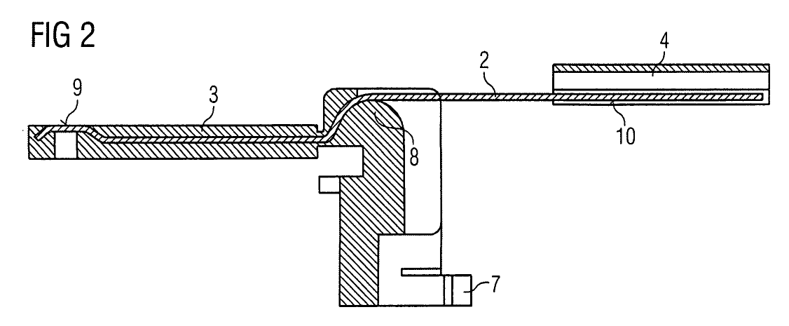

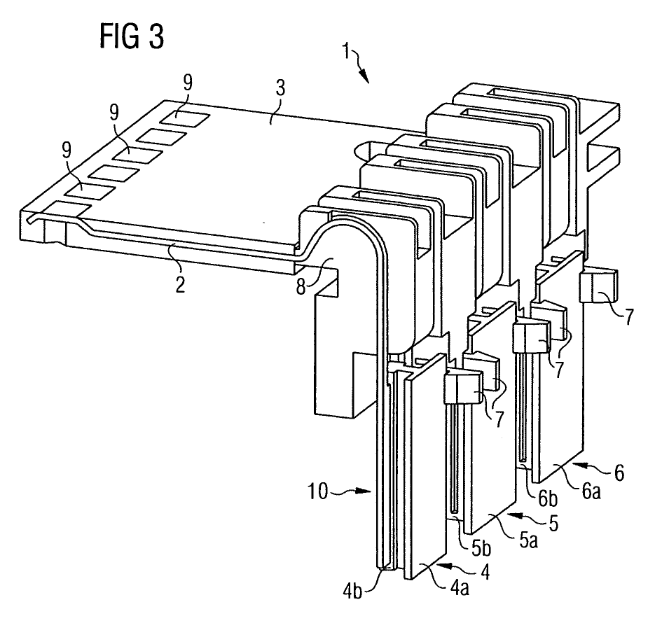

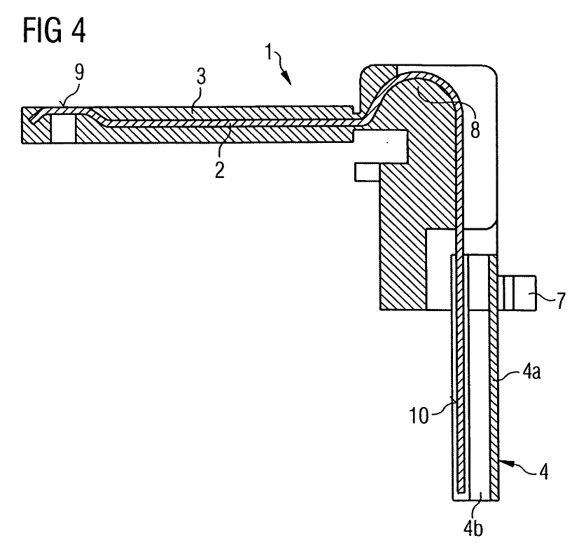

In FIGS. 3 and 4, the contacting component 1 is shown in the final assembled state. In order to reach this state, starting from FIG. 1 or 2, each valve plug 4, 5, 6 is bent down-wards by approximately 90° by bending around an integral bending collar 8 formed on the base component 3 so that the valve plugs 4, 5, 6, more precisely, the specific plate-shaped areas of the valve plugs engage with two latches 7 in each case that are also embodied integrally on the base component 3. By providing this snap-in locking device that consists of latches 7 as well as the plate areas 4a, 5a, 6a, the valve plugs 4, 5, 6 exist, a tolerance compensation is possible in both a parallel direction to the track conductors of the conductor device 2 (i.e. in FIGS. 3 and 4 perpendicular to the base component 3 up or down) and in a perpendicular direction to the track conductors of the conductor device (in FIGS. 3 and 4 perpendicular to the plate-shaped areas 4a, 5a, 6a of the valve plugs 4, 5, 6).

Contact between the contacting component 1 and the valves that are not shown is made for example on the contact area 10 via spring latches that are arranged on the valves. However, it is for example possible that the contacting component is permanently connected to the relevant contact areas 10 and also to the contact areas 9 with the neighboring components by means of welding. However, connections of the contacting component to the neighboring components are also feasible for example via further snap-in connections. The advantage of such connections as well as the snap-in connection 7 in the contacting component 1 is that these can again be solved relatively problem-free and that for example a faulty component can be replaced quickly and cost-effectively.

Therefore, a contacting component is provided according to the invention that is formed inside itself by engaging. Therefore, no special tools or devices are needed because the conductor device 2 can be manufactured by bending over on a bending collar 8 formed on the base component 3. Therefore, in the case of a short manufacturing period, the contacting component according to the invention has very low manufacturing costs and a very robust structure compared with the flexible foils of the prior art.

The previous description of the embodiment according to this invention is only used for illustrative purposes and not for purposes of restricting the invention. Different changes and modifications are possible within the framework of this invention without having to abandon the scope of the invention as well as their equivalents.

We claim:

1. A contacting component for manufacturing an electrical connection, in particular, between a control/regulation device and an actuator comprising a conductor device onto which at least one first plastic component and, separately from it, a second plastic component are molded in which case the conductor device can be bent in such a way that the first plastic component can engage in the second plastic component to provide an integral contacting component.

2. The contacting component according to claim 1, wherein the first plastic component and/or the second plastic component has a bending collar around which the conductor device can be bent.

3. The contacting component according to claim 1, wherein the first plastic component can engage in the second plastic component by means of a snap-in locking device.

4. The contacting component according to claim 1, wherein the first plastic component in the engaged state has an angle of approximately 90° to the second plastic component.

5. A method for manufacturing a contacting component that provides an electrically conductive connection, in particular, between an electronic or control/regulation device and an actuator including the following steps:
Providing a conductor device,
Molding a first plastic component and a second plastic component onto the conductor device wherein the second plastic component is arranged separately from the first plastic component, and
Bending the conductor device in such a way that the first plastic component engages in the second plastic component to obtain an integral contacting component.

6. The method according to claim 5, wherein at least one of the plastic components has a bending collar around which the conductor device can be bent.

7. The method according to claim 5, wherein the plastic components are molded simultaneously onto the conductor device.

8. The method according to claim 5, wherein the first plastic component is connected to the second plastic component by means of a releasable snap-in locking device.

9. The method according to claim 5, wherein the conductor device is removed from a flat blank in such a way that individual track conductors are interconnected via connecting bars and the connecting bars are removed after molding the plastic components.

10. The method according to claim 5, wherein the conductor device includes several separate track conductors which are kept in predetermined positions by means of a holding device and the plastic components are then molded onto the track conductors held in this position and the holding device is removed after the molding process has ended.

11. A contacting component for manufacturing an electrical connection, in particular, between a control/regulation device and an actuator comprising a conductor device onto which at least one first plastic component and, separately from it, a second plastic component are molded in which case the conductor device can be bent in such a way that the first plastic component can engage in the second plastic component to provide an integral contacting component, wherein the first plastic component and/or the second plastic component has a bending collar around which the conductor device can be bent, wherein the first plastic component can engage in the second plastic component by means of a snap-in locking device, and wherein the first plastic component in the engaged state has an angle of approximately 90° to the second plastic component.
